(19) United States
(12) Patent Application Publication
(10) Pub. No.: US 2006/0289675 A1
(43) Pub. Date: Dec. 28, 2006

(54) Chemical vapor deposition devices and methods

(76) Inventors: Miodrag Oljaca, Avondale Estates, GA (US); Trifon Tomov, Duluth, GA (US); George Andrew Neuman, Ann Arbor, MI (US); Doug Danielson, Decatur, GA (US); Andrew T. Hunt, Atlanta, GA (US); Travis Neumuller, Acworth, GA (US); Fred A. Fortunato, Roswell, GA (US); Henry A. Luten III, Ypsilanti, MI (US); Frank Witbrod, Cummings, GA (US)

Correspondence Address: ALFRED H. MURATORI;MICROCOATING TECHNOLOGIES, INC., 5315 PEACHTREE INDUSTRIAL BLVD, ATLANTA, GA, 30341-2107, US

(21) Appl. No.: 10/467,139

(22) PCT Filed: Dec. 27, 2001
(86) PCT No.: PCT/US01/49559

§ 371 Date: Mar. 8, 2004

Related U.S. Application Data
(60) Provisional application No. 60/265,735, filed on Feb. 1, 2001.

(51) Int. Cl. B05B 1/24

(52) U.S. Cl. 239/135

(57) ABSTRACT

Apparatus is described for rapidly coating a large area, or for rapidly producing a powder. In one embodiment, a liquid having a coating chemical is pumped from a liquid reservoir to a distribution manifold. From the distribution manifold, the liquid is carried under pressure to a geometric array, e.g., linear, of atomization nozzles. Flow equalization means are provided for equalizing the flow of the liquid delivered to each nozzle, and, preferably, means are provided for equalizing the temperature of the liquid delivered to each nozzle. The liquid, upon exiting the nozzles with the attendant pressure drop atomizes. The atomized liquid coats a substrate either in non-reacted or reacted form, or forms a powder. In a preferred embodiment, a solution of precursor chemical is reacted in a geometric array of flames produced at the nozzles, and a coating material produced in the flame coats the substrate, or a powder is formed. In another embodiment, vaporized precursor and vaporized are fed to a burner chamber having a linear exit slit. The vapor exiting the slit is burned, and material produced in a flame reaction are deposited on a substrate, or the powder formed is collected.

### GOVERNMENT CONTRACT

The United States Government has rights in this invention pursuant to Contract No. 70NANB8H4071 awarded by the Department of Commerce.

### FIELD OF THE INVENTION

The present invention is directed to devices and methods for producing coatings with chemical vapor deposition (CVD). In particular, the invention is directed to increasing the rate of deposition in combustion chemical vapor deposition (CCVD) by extending the combustion and deposition zone, e.g., extending it in a linear direction.

### BACKGROUND OF THE INVENTION

Vapor deposition is a well known method of producing coatings on substrates by exposing at least one surface of the substrate to a vapor phase of the deposition precursor. In CVD a chemical reaction of the precursor occurs on the surface of the substrate, or prior to deposition on the substrate to thereby form the coating on the substrate. The conventional methods of CVD require a chamber in which the substrate is held while the vaporized coating constituents are fed into the chamber. The portion of the vapor that does not deposit on the substrate to form the coating is exhausted out of the chamber where it must be collected for reuse or released into the atmosphere.

In the more recently developed CCVD techniques, a combustion source (flame, plasma etc.) is used to promote the chemical reaction in the vicinity of the substrate. In this manner the coating species is formed in close proximity to the substrate such that a larger portion of the coating precursor is deposited on the substrate. This is due to the increased control of the deposition reactions and temperatures. Many coatings will only form at a specific deposition temperature, and below this temperature, the coating will not form on the substrate and is exhausted away. With CCVD, changes of this deposition temperature can be made much quicker, as the surface of the substrate is (in some cases) directly heated by the combustion source such that as the combustion source forms the coating species, and the majority of the precursor forms the coating with very little of the precursor material needing to be exhausted. This can allow open atmosphere depositions without the need for reclamation of the exhausted materials. These processes are detailed in U.S. Pat. Nos. 5,652,021; 5,858,465; 5,863,604; 5,997,956; 6,013,318 and 6,132,653, and issued to Hunt et al. These patents, which are hereby incorporated by reference, disclose methods and apparatus for CCVD of films and coatings wherein a reagent and a carrier medium are mixed together to form a reagent mixture. The mixture, along with an oxidizing agent, is then ignited to create a flame or the mixture is fed to a plasma torch. The energy of the flame or torch vaporizes the reagent mixture and heats the substrate as well. These CCVD techniques have enabled a broad range of new applications and provided new types of coatings, with novel compositions and improved properties. In addition, these technologies are also useful in the formation of powders, as described in the above-referenced patents. A limitation of these previous CCVD processes is that the area coated by the combustion source is somewhat limited to the size of the combustion source, at least within reasonable time frames. The present invention is directed to overcoming this limitation by increasing the effective area coated by the combustion source, thereby increasing the overall rate of the deposition or powder production to a level appropriate for manufacturing processes.

The apparatus of the invention is useful in any deposition process in which a liquid is atomized and the atomized liquid is used to form a coating. While a flame is one energy source that may be used to promote chemical reaction of a precursor chemical(s) in liquid form, other energy sources, such as heated gases, induction heaters, etc. may be used, particularly if a non-oxidizing reaction is to be promoted.

### SUMMARY OF THE INVENTION

To achieve the above objectives, the present invention provides for methods and apparatus that include at least one increased dimension of the combustion source, particularly for CCVD processes. It should be understood that the various embodiments of the present invention are useful for other methods of deposition such as pyrolytic spray or CVD, and the following detailed description is most specific to the CCVD method for simplicity only. Furthermore, the described devices are also useful in the production of powders when used in conjunction with well known powder collection apparatus. When used to deposit coatings, the present invention allows a greater area to be coated by a single pass of the CCVD apparatus. A first embodiment is an integrated discrete linear flame that is comprised of a plurality of CCVD nozzles aligned in a linear array. Each of the discrete nozzles must be precisely controlled in terms of pressure and temperature to insure a uniform deposition rate and composition across the width of the CCVD apparatus. A second embodiment of the apparatus is in the form of a continuous linear flame wherein vaporized coating material is fed into an extended tube with a flame slit extending along the length of the tube. The coating material ignites as it exits the slit, thereby forming a continuous linear flame that provides a uniform deposition rate and composition along the length of the flame. Both of the embodiments provide an efficient method of producing a large area uniform coating on large substrates from a single chemistry solution, thus increasing deposition rates to a level suitable for manufacturing purposes.

In the first embodiment, several CCVD nozzles are arranged side-by-side. The typical deposition area or “footprint” of a single CCVD nozzle is dependent on several factors including but not limited to the material being deposited and distance from the substrate. In its simplest form, the multiple nozzle array consists of two deposition nozzles. The second nozzle may only increase the deposition area by a factor of 1.25, due to interaction effects between the two nozzles. The actual material throw rate, however, will typically increase by a factor close to 2.0. In order to maximize the coating uniformity, deposition area, and overall deposition material throw rate, the spacing between nozzles must be determined through experimentation for each particular application. Should the distance between nozzles for one of these factors interfere with another requirement, (such as maximizing deposition area at the expense of uniformity), two banks of nozzles may be arranged in succession, with the centerlines of the nozzles being offset to provide uniform coverage.

To provide uniform deposition between the multiple nozzles, the temperature and flow of each nozzle must be held constant with reference to the other nozzles. To achieve this requirement, back-pressure regulators and a block heater are employed. Each of the nozzles is fed from a common, chemistry solution, distribution manifold. Between the manifold and each nozzle, a back-pressure regulator is provided. The back-pressure regulator may be a standard pressure regulator, a needle valve, or a coiled tubing. Each of the nozzles has an inherent pressure drop in the fluid as it flows from the common manifold and out the exit of the nozzle. If this pressure drop is for example 100 psi in one nozzle, and 200 psi in a second nozzle, then the flow rate differential between these nozzles would be 50% (assuming an equal cross sectional flow area). By providing back-pressure regulators that increase the pressure drop to around 1000 psi, this same pressure drop difference of 100 psi only causes a pressure drop variation of 900 to 100 psi or a flow rate differential of 10%. In the preferred embodiment, the back-pressure regulators are in the form of coiled, small inner diameter tubes, the lengths of which determine the pressure drop for each nozzle. Thus to adjust for equal pressure drops and resulting uniform deposition material flow, the relative length of each tube is adjusted accordingly.

More specifically, since the effective flow rate of each orifice from a central manifold is inversely related to its back pressure, it is desired to maintain the back pressure to each line as closely as possible. Of particular importance to the present invention is the capability to maintain a uniform flow through multiple orifices from a single delivery system when the pressure drop across the orifices is not equal or as the pressure variation of an orifice varies over time (accumulation of material). Such a system exists, as per the present invention, when atomizing by releasing a thermally controlled liquid into a volume that is at a pressure below its boiling point relative to the controlled temperature of the liquid. Products to form the orifice are made with a large variation which results in different back pressures at the desired flow rate. Used alone, these orifices do not provide the desired control of the liquid through each nozzle. This is further complicated by the issue of heated liquids that can have variable amounts of material forming on the inside surfaces of the nozzles which causes a time variable back pressure at a constant flow rate. It is not desired to have a pump or liquid mass flow controllers (if one were found that works at the required pressures and flow rates) for each nozzle as the cost and maintenance becomes prohibitive. The current system works by have a precise pressure drop up stream from the nozzle to act in providing uniform flow to each nozzle. Downstream of this flow controlling pressure drop the liquid state would still be maintained so that material will not form over time on the walls of the flow controlling section. The pressure drop across this flow control region needs to be substantially higher than that of the orifice, so that any orifice pressure changes are minor in comparison to the constant pressure of the flow control section. Thus if orifice back pressure can vary from 100 psi to 300 psi, then the flow control pressure drop must be at least 2000 psi (10×) to maintain at least a 10% or better flow control through each nozzle. For even more uniform flow control, a 4000 psi (20×) pressure drop can be used (5% flow variation). For yet even more uniform flow control, a 10000 psi (50×) pressure drop can be used (2% flow variation). In some cases it will be desired to go to even a 100× factor (this would be a manifold pressure of 20,000 psi with a resultant pressure of 100 to 300 psi after the flow control section for the above example). Of course as higher pressures are needed the cost of the system increases, so added tolerance comes with a cost, complexity and size impact. This above example, without the flow control system of the present invention, would have a flow variation of about +/−50%. Available components (tubing, fittings, pumps, valves, etc.) for the present systems have significant price jumps at 5000, 10000, and 20000 psi. Thus there is desire to design a system with the exact level of flow variation required to produce the desired coating or powder, to avoid excessive costs.

The flow rate of the deposition material is also dependent on other factors, such as density and viscosity, that are in turn dependent on the temperature of the fluid. In order to maintain a similar temperature between the nozzles, a block heater is used. Each of the nozzles and a thick walled tube leading to the nozzle from the coiled tube is encased in a block of material that is thermally conductive (such as a dense metal). Alternatively, precision-machined orifices may be drilled into the material to form the nozzles and passageway between the nozzles and the coiled tubes. Resistive element heaters are used to heat the block of material such that the fluid flowing through the nozzles is brought to a thermodynamically metastable state. A liquid is in a metastable state if its temperature at the exit of the nozzle is higher than its saturation temperature for a given pressure. By heating the fluid to this temperature, rapid expansion of the liquid is achieved which results in quick and uniform atomization of the precursor material.

It should also be understood from the following description, that the apparatus and methods of the present invention can be used to form coatings using deposition techniques other than CCVD, as the use of a combustion source is not necessary for forming some materials. The linear deposition apparatus provides a uniform material deposition rate along its length, thereby forming a more uniform coating than could be previously achieved using prior art devices and techniques. This is due to the pressure and temperature regulation provided between the array of nozzles that form the integrated linear deposition apparatus.

A second embodiment of the present invention provides a continuous linear deposition apparatus for applying coatings using precursor chemical-containing fluids.

### BRIEF DESCRIPTION OF THE DRAWINGS

FIG. 1 is a top view of an integrated, discrete flame deposition apparatus of the present invention.

FIG. 2 is a side view of the deposition apparatus of FIG. 1.

FIG. 3 is a top view of a continuous flame deposition apparatus of the present invention.

FIG. 4 a side view of the continuous flame deposition apparatus of FIG. 3.

FIG. 5 is a top view of an alternative embodiment of the continuous flame deposition apparatus.

FIG. 6 is a top view of a further alternative embodiment of the continuous flame deposition apparatus.

FIG. 7 is a diagram showing a circular arrangement of nozzles.

### DETAILED DESCRIPTION OF THE PREFERRED EMBODIMENTS

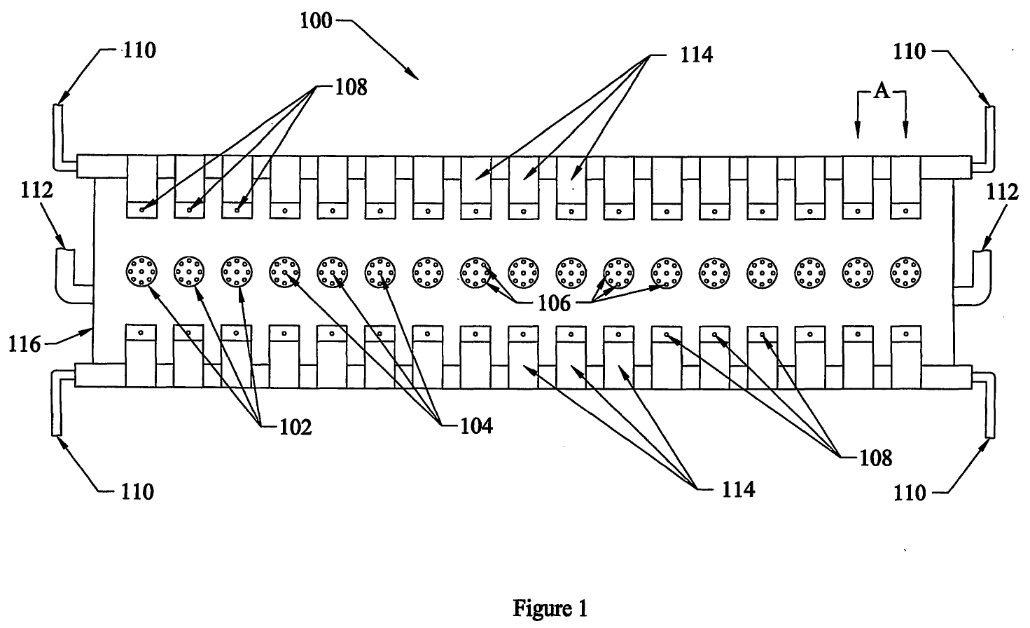

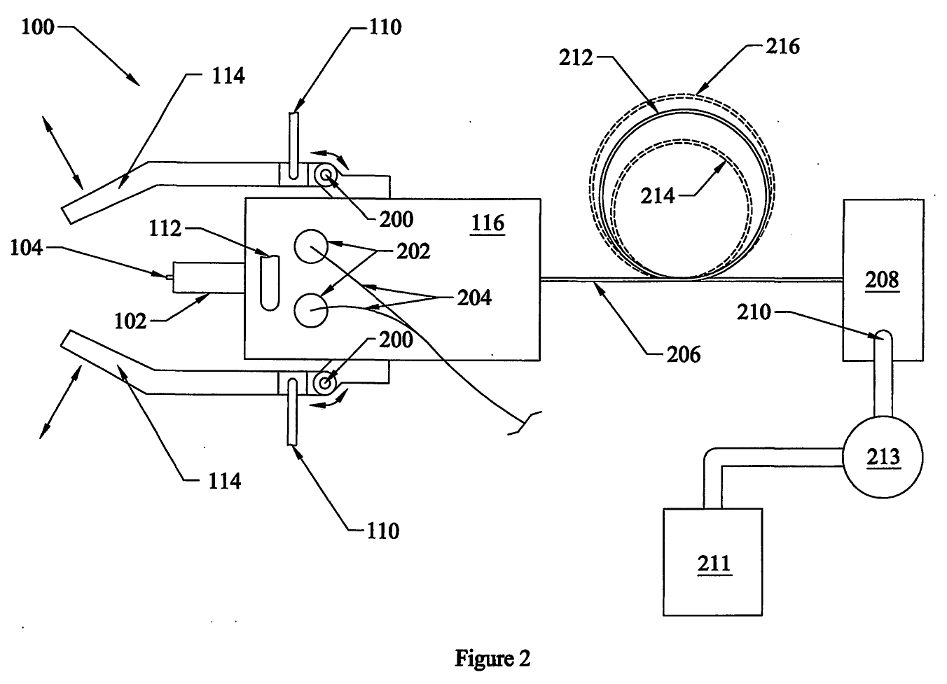

The integrated nozzle embodiment 100 of the present invention is illustrated in FIGS. 1 and 2. The integrated discrete flame deposition apparatus 100 includes a main body portion 116 having a plurality of discrete nozzles 102, such as those used for CCVD, linearly arranged across the width of main body portion 116. Each of the CCVD nozzles 102 includes a central atomizing liquid delivery tube 104 surrounded by a number of oxygen (or other deposition gas) delivery orifices 106. On both sides of each nozzle 102 a pilot flame nozzle 114 is located. Each of the pilot flame nozzles 114 includes an orifice 108 that provides a combustible gas (such as methane propane, hydrogen, etc.) that is ignited to form a pilot flame for each CCVD nozzle 102. While some precursor solutions are combustible enough to maintain a flame, others may require pilot flames to ensure constant and uniform burning of the precursor solution that exits orifice 104. Therefore pilot flame nozzles may not be required, or more than two pilot flame nozzles may be needed for each CCVD nozzle, or alternatively, the pilots may be in the form of a continuous flame provided from a slit-shaped nozzle. Each of the pilot flame nozzles 114 are rotatably mounted to main body portion 116 such that they can pivot about axis 200. This allows the spacing between each pilot flame nozzle 114 and CCVD nozzle 102 to be adjusted for optimum performance. Conduits 112 and 110 convey the appropriate gas to the tip oxygen orifices 106 and the pilot flame orifices 108, respectively. The conduits need to be of sufficient size to enable uniform flow through all orifices.

To maintain a uniform precursor flow rate between the nozzles 102 (and therefore a more uniform coating), each liquid delivery tube 104 is attached to a liquid distribution manifold 208 via a flow equalization tube 206. Each of the flow equalization tubes includes a pressure regulating means 212, shown here as a loop of tubing, although other means may be used to equalize the flow between nozzles. For examples, the tubes could be of equal length, but different interior diameter, although it is most convenient to adjust tube length rather than diameter. Or the sizes of openings from manifold 208 could be of different, but precisely measured size. In order to increase the pressure drop between the liquid distribution manifold 208 and a liquid delivery tube 104, a longer length, larger diameter loop 216 is formed in the flow equalization tube 206. Conversely, in order to decrease the pressure drop between the liquid distribution manifold 208 and a liquid delivery tube 104, a smaller diameter loop 214 is formed in the flow equalization tube 206. By providing large pressure changes through the precise flow equalization tubes going into the liquid delivery tubes 104, equal flow rates of liquid can be realized between the nozzles 102 (assuming equal liquid temperatures). A liquid supply tube 210 delivers the liquid that is pumped by pump 213 from liquid reservoir 211 to a liquid distribution manifold 208. FIG. 2 shows only one of flow equalization tube 206 exiting the manifold 208; however it is to be understand that all of the equalization tubes 206 that feed the nozzles 104 of the array exit the manifold 208. The pump 213 pressurizes the liquid so that the liquid exhibits a large pressure drop as it eventually exits the flow equalization tube 206 and another, smaller, pressure drop across the nozzle 104. Should active pressure regulation be required, pressure regulating valves and sensing means can be used in conjunction with or in place of the flow equalization tubes 206.

The liquid may simply be a liquid material that forms a coating without reaction, e.g., a solution and/or suspension of a material that is to be deposited on a substrate. Controlled atomization will help to provide a uniform coating in such case. In the illustrated apparatus adapted for CCVD, the liquid in reservoir 211 is a solution of one or more precursor chemicals which, in conjunction with an oxidizing agent, particularly oxygen, undergoes a flame reaction that produces the material that is deposited as the coating. Energy sources other than flame may be used to react precursor chemicals in atomized liquids so as to produce coating materials.

A very important advantage of the above-described apparatus is the ability to precisely control the flow rates through multiple outlets using back-pressure regulators for individual supply lines. This provides ability to induce controlled pressure drop in each supply line that is at least 5-10 times larger than the pressure drop in the discharge nozzle. The goal of the feed design it to minimize the effects of these pressure variations that can vary as nozzle orifices 104 are changed and as the nozzle ages.

An important aspect of the present invention is the temperature of the precursor solution as it exits the orifices 104. One method to maintain a uniform temperature for the precursor solution is by heating the main body portion 116 using heating elements 202 that are embedded therein. The heating elements 202 are supplied electrical power via wires 204. Wires 204 may include two conductors for each element. Alternatively, the elements may be electrically grounded by the main body portion 116 if it is formed from electrically conductive material, in which case only a single conductor is needed to power each element 202. As the main body portion 116 is constructed of thermally conductive material, the elements heat the entire main body portion 116 as well as the liquid delivery tubes 104, and the liquid flowing therethrough. Of course it should be understood that the liquid delivery tubes 104 may be in the form of small orifices drilled or otherwise formed directly through the main body portion 116, without the need for separate tubes. In either case, by heating the main body portion, each nozzle delivers the liquid solution at the same temperature thereby greatly increasing the uniformity of the resulting coating. The degree of atomization, i.e., the droplet size, is determined in part by the temperature of the solution in the nozzle; the higher the temperature, the smaller the droplet size. Another important aspect to consider in constructing the integrated discrete flame deposition apparatus 100 of FIGS. 1 and 2, is the distance A between the centers of adjacent nozzles 102. Considering the apparatus in its simplest embodiment (a two-nozzle array or integrated system) the effective deposition area is increased by at least a factor of 1.25 over a single nozzle system. While the effective area or deposition width is not necessarily increased by a factor of two due to possible interaction effects between the nozzles, the overall deposition material throw rate may increase by a factor close to two. Each nozzle, in its simplest form, typically has a radial bell distribution of coating thickness, the exact footprint being dependent upon the material being deposited and the exact processing parameters. Some experimentation is often needed to determine the optimum spacing A between the nozzles such that the coating uniformity, deposition area and overall deposition material throw rate are optimized. There may be inherent compromises between these factors that will be application dependent. Any limitations in optimizing this distance can be overcome by using additional arrays or nozzles with offset positioning of the centerlines of the nozzles between the two or more deposition apparatuses 100.

The integrated nozzle apparatus described above is particularly suited to vapor deposition (such as CCVD) or spray deposition methods, such as pyrolytic spray onto large substrates, e.g., glass and sheet material. The deposition material throw rate and coating uniformity of the single-flame CCVD system were previously limited by the size of the deposition apparatus/nozzle. In a production environment, an array of flames has the potential to improve deposition material throw rate and uniformity due to increased flow precursor throw rates by using larger deposition zones. The integrated nozzle or discrete nozzle array provides uniform and efficient atomization and delivery of the liquid solution across a relatively large deposition area. It is important to note that the invention allows flexibility in designing the nozzle geometry (linear bank of flames, radial distribution of flames, or rastering arrangement), and almost unlimited expansion in the size. Because the individual supply tubes are connected (in parallel) to a common manifold, the additional lines do not result in increased pressure required by the pump. The manifold needs to be of sufficient size to enable little pressure variations along its length, so that the flow is better regulated. This feature of the present invention makes it particularly attractive for scale-up applications where high deposition rates and uniform large coverage areas are critical, using deposition equipment having a variable pressure drop component.

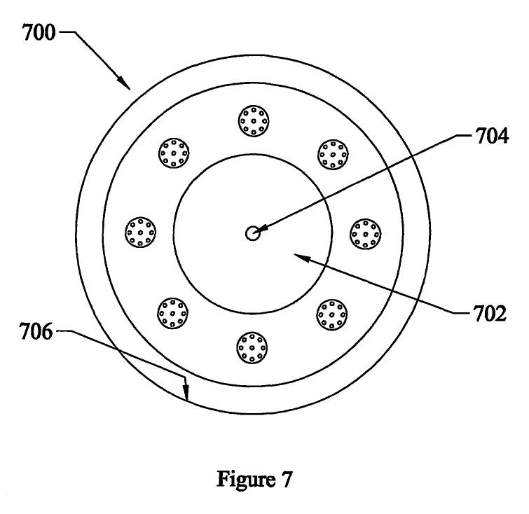

The linear array of nozzles is shown in an array geometry particularly advantageous for many coating applications, such as for coating a continuously moving web of material. Other array geometries may be used for particular coating applications. For example, as shown in FIG. 7, an array of nozzles 700 may be arranged in a circle for rapidly coating individual work pieces or for coating a strand 704 extending through center opening 702, or for coating the inner surface of a circular substrate 706. A partial circle (curve) geometry may also be used. Regardless of geometry of the array, equalization of temperature and flow promote uniform coating. The specific examples of form and shape are not to be deemed as limiting, as a wide range of forms and shapes are desired (as a many forms and shapes of substrates and powder collecting means can be used).

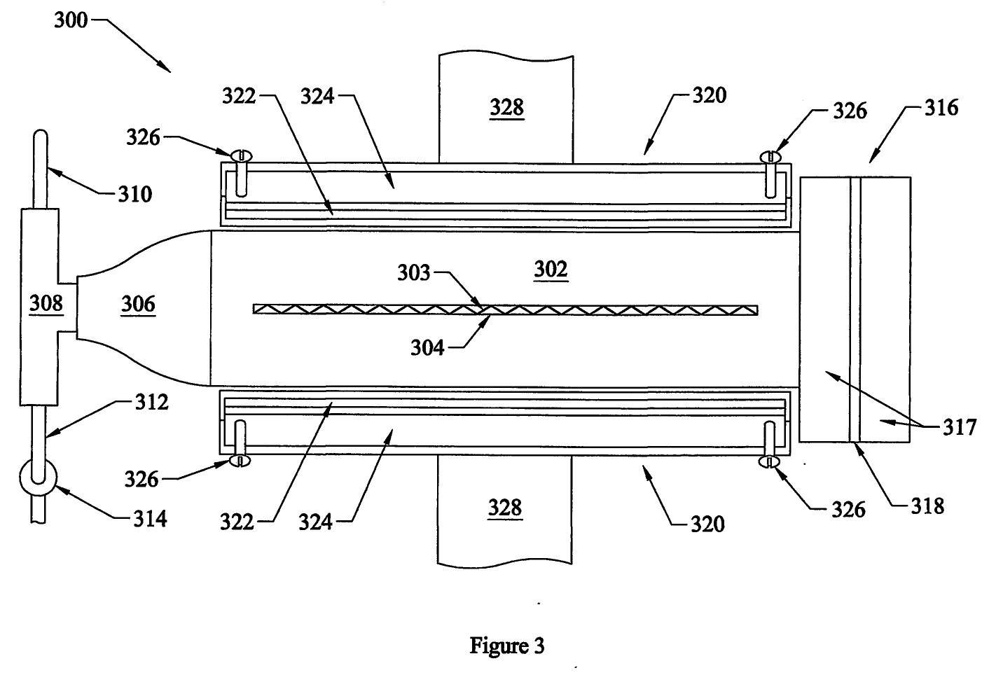

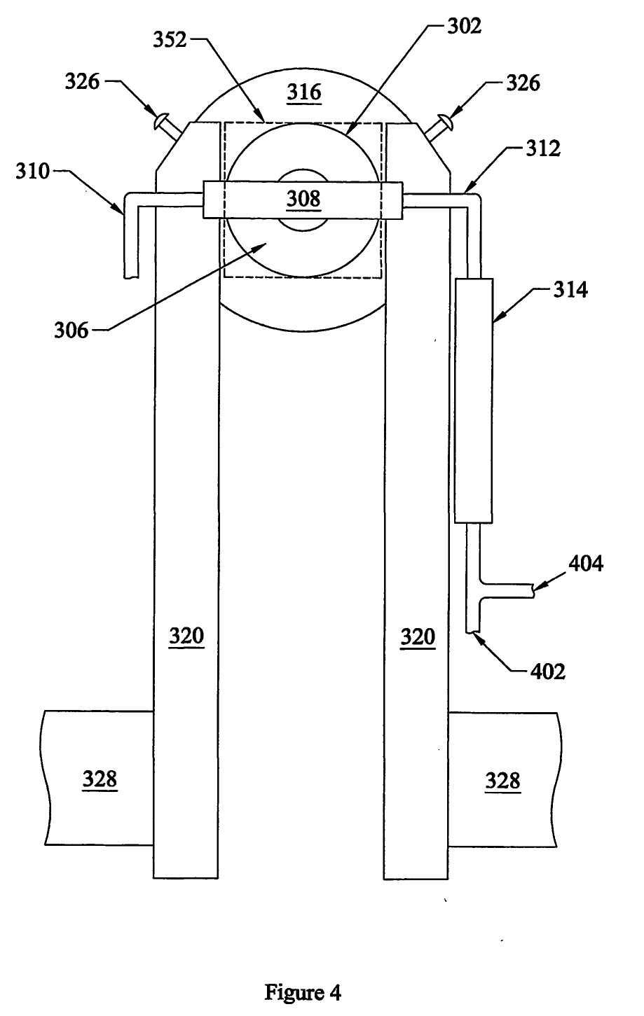

In FIGS. 3 and 4, a second embodiment of the deposition apparatus 300 of the present invention is illustrated. In this embodiment, a continuous linear flame is produced using a burner 302 having a central linear burner slit 304 extending longitudinally along one side of the tube. The illustrated burner 302 is a tube defining an interior gas chamber from which the gaseous or vaporized materials exit through the slit 302. The term “linear slit” in this context is intended to mean a slit that is at least 5 times the dimension in the linear dimension than its with, preferably at least 20 times, but often much longer than its width. A corrugated member or diffusion grating 303 within the slit 304 assists in maintaining a steady and uniform flame along the length of the slit 304. The grating 303 prevents fluttering of the flame along the burner slit 304.

A gaseous precursor mixture is fed to the burner 302 from a mixing manifold 308 through an conical connector 306. In the illustrated embodiment, the mixing manifold 308 is fed by a conduit 310 that may contain a flammable gas that provides the main thermal energy and a conduit 312 that carries a gas-carried precursor solution. In the illustrated embodiment, the conduit 312 is fed by conduits 402 and 404. One of these conduits 402 may feed air that entrains precursor solution from a reservoir (not shown), such as a bubbler or sublimer, and the other conduit 404 may carry a fuel and/or oxygen to form a combustible mixture. Conduit 312 is shown passing through a heating unit 314, e.g., an inductive heater, to preheat the gases passing therethrough. Although not shown in the illustrated embodiment, a pre-heater could be used to heat the gas-carried precursor in conduit 310. For apparatus efficiency, however, generally only one of the gas streams is pre-heated, as sufficient heat may be provided to only one of the gas streams to provide the desired pre-heating energy for efficient operation. Such preheating of some or all of the gases may help to reduce the amount of fuel required for combustion and to more precisely control the vapors produced in the flame.

At the end of the burner unit 302 is an overpressure relief device 316 that may simply be a rupture-able diaphragm 318 held between a pair of plates. Alternatively, a more elaborate relief valve may be used.

While not required to form the coating, it may be beneficial to have exhaust gasses exit through exhaust plenums 320 and then through exhaust conduits 328. In a preferred mode of operation, exhaust conduits 328 are each connected to a vacuum (not shown). To more precisely control the exhaustion of gases, the illustrated plenums each have a rotating exhaust plate 324 that controls the size of the exhaust slots 322. The rotating plates in the illustrated embodiment are manipulated by set screws 326. By controlling the exhaust to each side of the burner unit, the depositing gasses can be evenly spread out as they exit the burner.

Because of the large volume of space in the burner unit 302, the pressure through the burner slit 304 is generally equal from one end to the other. If greater equality of pressure is desired, various means may be used to more precisely equalize pressure along the length of the burner slot. For example, the burner slit 304 could be slightly wider at the downstream end than the upstream end. Or the burner unit 302 could be connected to the mixing manifold 308 from a central location behind the burner slit 304. The mixing manifold 308 should be of sufficient cross sectional size, that little variation in pressure exists along its length.

It is also possible to have other configurations of the elongated burner slit, in which case the burner may be rectangular in cross section such that the top face of the burner is flat as shown by dotted line in FIG. 4. For example, the slit could be of a wave configuration or a substantially circular configuration (with a center portion supported by struts).

While the illustrated apparatus mixes oxidizing gas (oxygen) with the vaporized fuel/precursor mixture prior to introduction of the gaseous components into the burner unit 302, external oxygen in the air could be relied upon to maintain combustion of fuel/precursor exiting the slit 304.

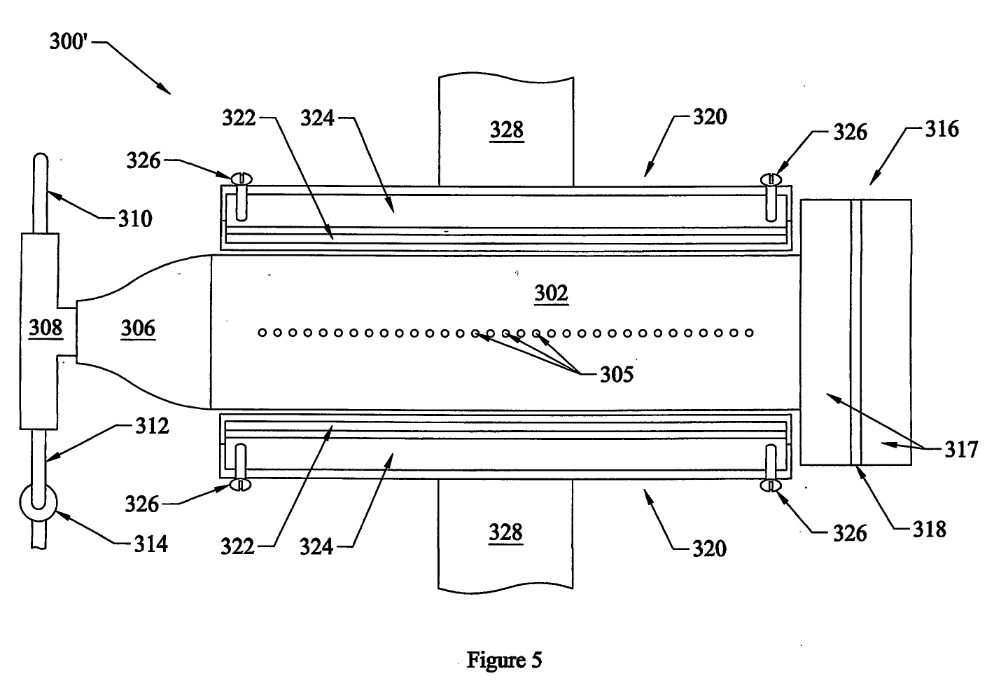

Illustrated in FIG. 5 is an alternative embodiment of a linear spray apparatus 300′ apparatus of the present invention. In this embodiment, the linear slit 304 of FIG. 3 is replaced by a linear array of orifices 305 which are spaced sufficiently close together so as to provide a generally continuous linear flame. In this embodiment, the fluid in the burner chamber 302 could be either in gaseous or liquid form. With the correct combination of orifices 305 of appropriately small size, temperature and liquid pressure, the liquid would atomize as it exited the chamber.

Although the FIG. 3-4 and FIG. 5 embodiments are illustrated as linear, either the slit 304 (FIG. 3-4) or linear array of orifices 305 (FIG. 5) could be of other geometric arrangement, such as circular (as shown in FIG. 7 with respect to the embodiment of FIGS. 1 an 2), square or rectangular. To facilitate non-linear slit 304 or orifice array 305 configurations, the burner chamber might have a flat top face from which fluid exits the chamber through the slit 304 or orifice array 305.

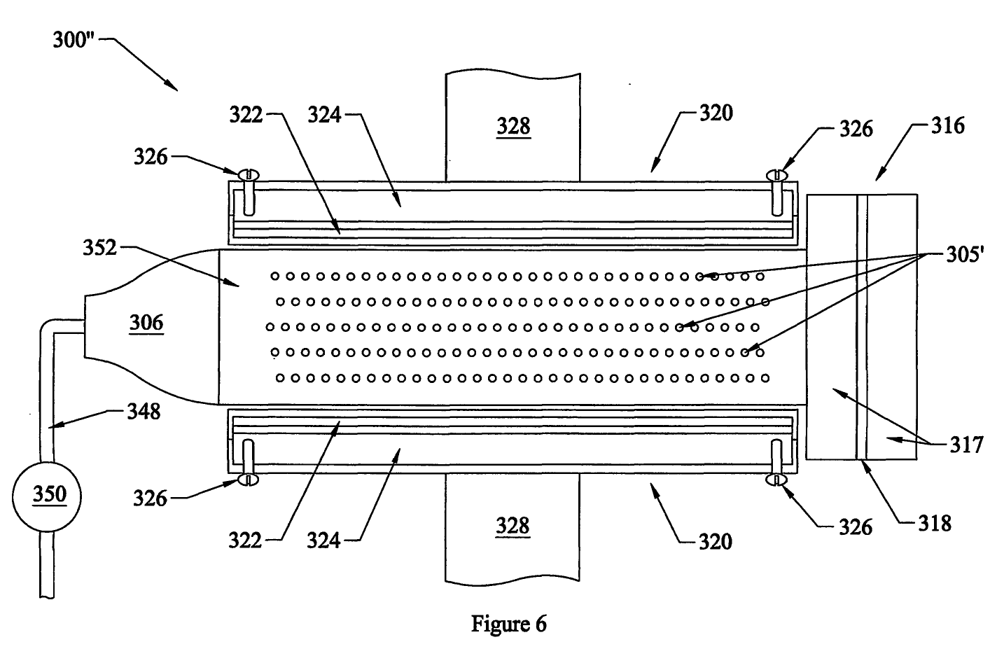

Illustrated in FIG. 6 is a further alternative embodiment 300″ of the present invention. In this case, the burner face 352 is flat and rectangular, with the burner having a rectangular cross section (shown by dotted line in FIG. 4). An array of very small orifices 305′, in this case in a rectangular configuration array, provide the fluid outlet and flame source. While gases could be burned in this burner, the FIG. 6 embodiment is shown with a fluid conduit 348 leading to the connector 306; the conduit carries liquid pressurized by pump 350. While many possible arrays can be used, the linear arrays 305′ in FIG. 6 are shown with offset centerlines to provide uniform coverage of the coating.

What is claimed is:

1. Apparatus for producing a uniform flow aerosol of a liquid comprising:
liquid reservoir means containing the liquid at a first temperature;
means for pressurizing said liquid;
liquid distribution manifold means, said pressurizing means delivering pressurized liquid to said liquid distribution manifold means,
an array of thermally controlled nozzles, said nozzles each being configured such that the liquid reaches a second temperature in each of said nozzles and at the exit of each of the nozzles undergoes a pressure drop to a pressure below the liquid's boiling point relevant to the second temperature, and is thereby atomized,
means to deliver the liquid from said manifold means to each of said nozzles, said delivery means having flow equalization means which use back pressure, whereby liquid flow is more uniformly delivered to and from each of said nozzles.

2. Apparatus according to claim 1 having means to preheat the liquid delivered to each of said nozzles at an equalized temperature.

3. Apparatus according to claim 1 having energy means associated with each of said nozzels to promote a chemical reaction of at least one component of said liquid so as to produce a powder or coating material.

4. Apparatus according to claim 1 wherein each of said nozzles has associated means for delivering an oxidizing agent in the region of said nozzle, whereby at least one component of said atomized liquid is oxidized to produce a powder or coating material.

5. Apparatus according to claim 1 wherein each of said nozzles has associated means for delivering a combustible agent in the region of said nozzle, whereby at least one component of said atomized liquid is combusted to produce a powder or coating material.

6. Apparatus according to claim 1 wherein said flow equalization means comprises a plurality of conduits, a conduit from said manifold leading to each of said nozzles, the dimensions of each of said conduits being such that liquid of substantially equal flow is delivered to each of said nozzles.

7. Apparatus according to claim 1 wherein said array comprises a linear array of said nozzles.

8. Apparatus according to claim 1 wherein said array comprises a circular array of said nozzles.

9. Apparatus according to claim 1 wherein said array comprises a curved array of said nozzles.

10. Apparatus according to claim 1 wherein the pressure of the liquid in said manifold means is less than 5,000 psi.

11. Apparatus according to claim 1 wherein the pressure of the liquid in said manifold means is less than 10,000 psi.

12. Apparatus according to claim 1 wherein the pressure of the liquid in said manifold means is less than 20,000 psi.

13. Apparatus according to claim 1 wherein the variation of liquid flow rate between any two of said nozzles is less than 10%.

14. Apparatus according to claim 1 wherein the variation of liquid flow rate between any two of said nozzles is less than 5%.

15. Apparatus according to claim 1 wherein the variation of liquid flow rate between any two of said nozzles is less than 2%.

16. Apparatus for depositing a coating material comprising
a burner unit comprising a liquid chamber and a liquid opening means exiting said liquid chamber wherein said opening means is elongated in at least one direction, means to provide to said liquid chamber at least one precursor chemical in liquid form and, means to ignite said liquid to produce said coating material from said precursor chemical.

17. The apparatus of claim 16 further having means to provide an oxidizing agent to said chamber in gaseous form.

18. The apparatus of claim 16 having pre-heating means to pre-heat at least one precursor chemical in liquid form fed to said gas chamber.

19. The apparatus of claim 16 wherein said elongated opening means is linear.

20. The apparatus of claim 16 wherein said opening means is an elongated slit

21. The apparatus of claim 16 wherein said opening means comprises a plurality of orifices.

22. The apparatus of claim 21 having means to provide said precursor chemical to said chamber in pressurized liquid form and said orifices are sized sufficiently small such that pressurized liquid exiting said chamber atomizes via some boiling as it leaves said orifices.

23. Apparatus for depositing a coating material comprising
a burner unit comprising a fluid chamber and a fluid opening means exiting said fluid chamber wherein said opening is elongated in at least one direction, means to provide to said fluid chamber at least one precursor chemical in fluid form, and means to ignite said fluid to produce said coating material from said precursor chemical.
